(19) United States
(12) Patent Application Publication
(10) Pub. No.: US 2003/0075713 A1
(43) Pub. Date: Apr. 24, 2003

(54) Heterojunction bipolar transistor

(76) Inventors: Rajashekhar Pullela, Westlake Village, CA (US); Mark Rodwell, Goleta, CA (US)

Correspondence Address: TEJINDER SINGH, NEWPORT LAW GROUP, 5001 BIRCH, NEWPORT BEACH, CA, 92660, US

(21) Appl. No.: 10/032,779

(22) Filed: Oct. 22, 2001

(51) Int. Cl. H01L 29/06

(52) U.S. Cl. 257/20

(57) ABSTRACT

A heterojunction bipolar transistor is provided with a graded band gap layer between a base and subcollector region. The graded band gap layer minimizes the surface leakage current path between the base and subcollector.

### BACKGROUND OF THE INVENTION

1. Field of the Invention

The present invention relates to semiconductor devices, and more particularly to heterojunction bipolar transistors.

2. Background

Bipolar transistors are used extensively in various electronic industries. Typically, a bipolar transistor consists of three doped semiconductor layers operating as a P-N-P or N-P-N transistor. A PNP transistor and an NPN transistor have different polarities and, for any given state of the transistor operation, the current directions and voltage polarities for each type of transistor are exactly opposite of each other. The three layers of a conventional bipolar transistor are called (i) Collector; (ii) Base; and (iii) Emitter.

Bipolar transistors operate as current-controlled regulators, and depending upon a base current, restrict the amount of current that can pass through the transistor. A main or collector current travels from the collector to the emitter, or from the emitter to the collector layer, depending on the type of the transistor and the base current travels from the base to the emitter or vice-versa, depending upon the type of the transistor.

A heterojunction bipolar transistor (referred to herein as “HBT”) typically has different band gaps at the junctions. Indium-phosphide (InP) based HBTs are being developed for commercial use in wireless and fiber optics communication systems because of high performance needs.

Conventional HBTs fail during operations due to surface leakage, especially between the base and collector layers, because exposed surfaces in the base layer of various semiconductors are conductive. InP based HBTs include InGaAs, InAlAs as well as InP, and during semiconductor processing, exposed semiconductor surfaces may get contaminated and oxidized, and the oxidized layers produce leakage currents. Indium oxide, Gallum oxide, Aluminum oxide, Arsenic and Phosphorous due to such contamination alter the semiconductor energy band structure, producing high density of electron energy states within the energy bandgap between conduction and valence bands. Based upon transistor geometry and applied voltage, the contaminants result in a high surface concentration of electrons or holes and thereby allow the semiconductor surface to conduct current.

FIGS. 1A-1C show various views of a conventional HBT, where FIG. 1A shows a cross-sectional view, FIG. 1B shows the top view and FIG. 1C shows a side view of the FIG. 1A HBT. Referring now to the cross-sectional view of FIG. 1A is HBT 100 fabricated on a semiconductor substrate 102 with dielectric filler material 101. HBT 100 includes a subcollector layer 103, a collector region 104, a p⁺ doped base semiconductor layer 105, and an emitter layer 108. HBT 100 includes base contact metal layer 106, and collector contact metal layer 110. Also included are collector contact metal 111, emitter contact metal 109 and base contact metal 107 for external HBT connection.

Referring now to the top view of HBT 100 in FIG. 1B, is dielectric filler metal 101, and subcollector layer 103. Also shown are base contact metal 107, emitter contact metal 109, and collector contact metal 111 over base contact metal 106 and collector contact metal 110.

FIG. 1C shows semiconductor substrate 102 with dielectric filler 101. Also shown are subcollector layer 103, collection layer 104, p⁺ doped base region 105, emitter semiconductor layer 108, and base contact metal 106. FIGS. 1A and 1C also show the encapsulated transistor surface 112, where surface 112 includes Silicon Nitride (SiₓNy) to prevent contamination.

FIGS. 2A-2C illustrate the semiconductor surface leakage path. FIG. 2A is the cross-section view of HBT 100 as described in FIG. 1A and shows leakage path 113 between base layer 105 and collector layer 104 due to surface contaminants discussed above. Leakage path 113 is also shown in top view FIG. 2B.

As stated above, Silicon Nitride encapsulation layer 112 is used to avoid surface contamination. If contamination occurs regardless of layer 112, the contaminants may then be removed by chemical etching. However, the chemically etched surface re-oxidizes very quickly after etching and upon exposure to the atmosphere, and thereafter the leakage current resurfaces.

Another conventional solution to eliminate contamination is to vacuum clean the surface and then immediately encapsulate the transistor with an inert material, for example, Silicon Nitride, before the semiconductor leaves the vacuum. Such vacuum cleaning is expensive and has process constraints that reduce the overall yield of the semiconductor manufacturing process, making encapsulation an expensive solution.

Yet another conventional solution is to encapsulate the transistor in a polymer coating of either polyamide or Benzocyclobutene. Such polymer passivation/encapsula-tion techniques have drawbacks in high volume semiconductor manufacturing. Also, spin coating of HBT wafers with polymide often leaves voids in the polymer film adjacent to the transistor junction. Such voids are difficult to passivate and may cause the device to fail anyway during operation. Furthermore, such voids are difficult to detect because they cannot be detected visually, without destruction of the semiconductor wafer. Therefore, the polymer or polyamide solution is not effective.

Therefore, there is a need for a reliable HBT design such that surface leakage is minimized and leakage current does not interrupt the operation of the transistor.

### SUMMARY OF THE INVENTION

In one aspect, the present invention addresses the foregoing deficiencies by providing a HBT with a graded band gap layer between the HBT subcollector and base region. The graded band gap layer is lightly doped and includes InGaAs and InAlAs.

In another aspect of the invention, the graded band gap layer is undepleted under a low voltage bias, and is depleted under a high voltage device.

In yet another aspect, the graded band gap layer is epitaxially grown. In another aspect, the graded band gap layer breaks the surface current path from the base to such collector region.

In yet another aspect of the present invention surface current path is broken without expensive cleaning or packaging techniques.

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

FIG. 1A as described above is a top view of a conventional HBT.

FIG. 1B as described above is a cross-sectional view of the FIG. 1A HBT.

FIG. 1C as described above is a side view of the FIG. 1A HBT.

FIGS. 2A-2C show the base collector leakage path in the FIG. 1A HBT.

FIG. 3A is a top view of a HBT, according to an embodiment of the present invention.

FIG. 3B is a cross-sectional view of a HBT, according to an embodiment of the present invention.

FIG. 3C is a side view of a HBT according to an embodiment of the present invention.

FIG. 3D is a detailed cross-sectional view of the collector/emitter region of the FIG. 3A HBT.

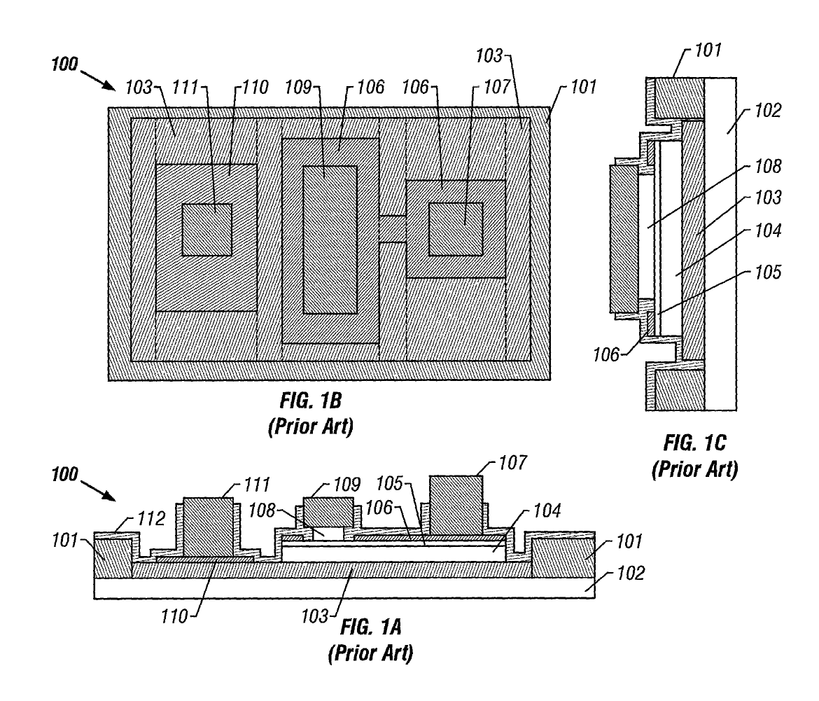

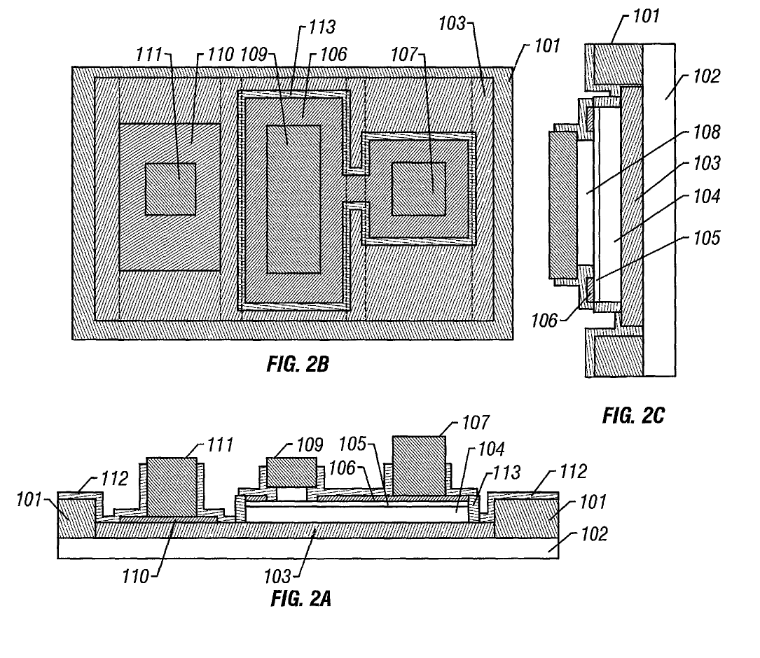

Features appearing in multiple figures with the same reference numeral are the same unless otherwise indicated.

### DETAILED DESCRIPTION OF THE PREFERRED EMBODIMENTS

In one aspect of the present invention, a HBT is provided with a graded band gap layer which is epitaxially grown; is lightly doped (n⁺); includes InGaAs and InAlAs; is undepleted under a low voltage bias and depleted under a high voltage bias; and breaks the surface leakage current path from the base to the subcollector region without expensive cleaning and/or packaging.

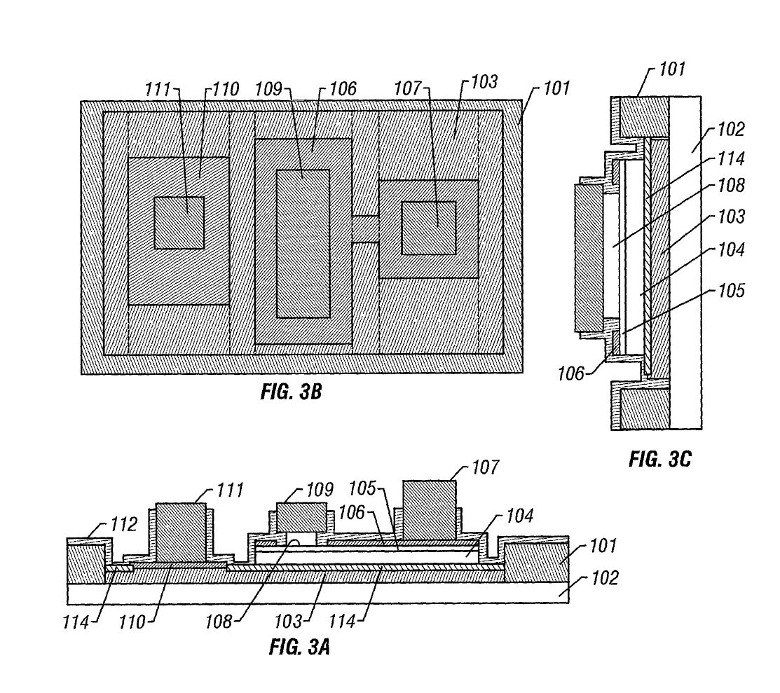

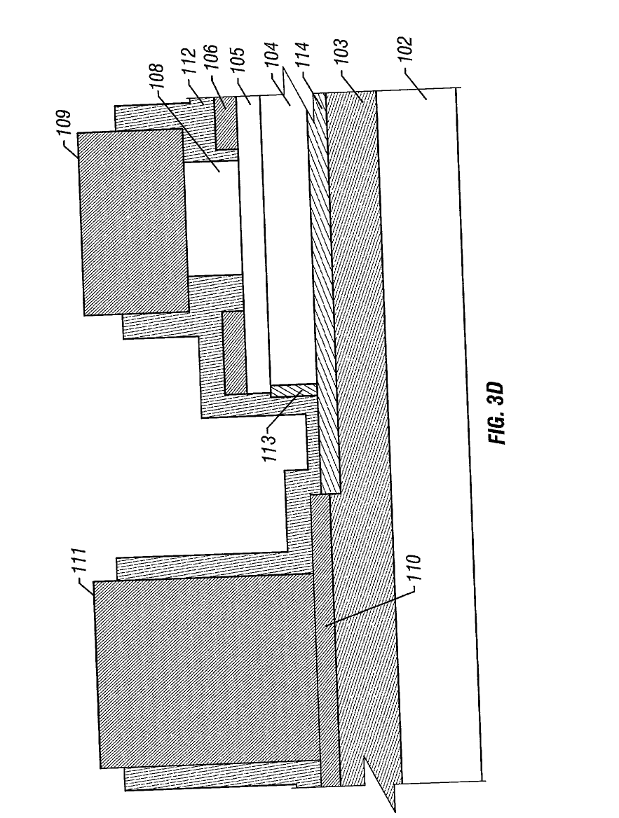

Referring now to the cross-sectional view of FIG. 3A, is HBT 300 with semiconductor substrate 102 that has Indium Phosphide and dielectric filler material 101. A subcollector region 103 having Indium, Gallium, and Arsenide (InGaAs) with n⁺ doping are used. Typically, the subcollector region 103 comprises of plural layers with thickness approximately ranging from 1000-3000 Angstrom with Silicon doping of approximately 1E 19 cm⁻³. It is noteworthy that the invention is not limited to a particular thickness, a range of thickness or specific doping levels for region 103.

Also shown is collector region 104 which includes plural Indium Phosphide (InP) layers (n⁺ doped) with thickness ranging from approximately 2000-4000 Angstrom. The 2000-4000 Angstrom layers have Silicon doping ranging from approximately 1E16 cm⁻³ to 3.2E 16 cm⁻³.

Base region 105 is p⁺ doped and includes InGaAs with an approximate thickness range of 300-700 Angstrom. Base region 105 has Beryllium or Carbon doping of approximately 4E 19 cm⁻³ to 1E 20 cm⁻³ .

Emitter layer 108 is also n⁺ doped and includes InGaAs. Emitter region 108 comprises of plural InGaAs layers with thickness approximately ranging from 500-3000 Angstrom.

It is noteworthy that the invention is not limited to any particular thickness, range of thickness or doping levels for collector region 104, base region 105 and emitter region 108.

HBT 300 uses plural metal contact layers including base contact metal 106 and collector contact metal 110 with external metal contacts including collector contact 111, emitter contact 109 and base contact 107. The foregoing metal contacts may include titanium, platinum and gold alloys.

HBT 300 also includes a lightly doped graded band gap region 114. Graded band gap region 114 is approximately 200-400 Angstrom and includes InGaAs, and Indium Aluminum Arsenide (InAlAs). Graded band gap region 114 with the n+ doping is used as a base collector ledge to minimize surface current between base region 105 and collector region 104. Graded band gap region 114 is undepleted under low voltage bias and depleted under high voltage. Grade band gap region 114 has Silicon doping of approximately 2E 19 cm⁻³. It is noteworthy that the invention is not limited to a particular thickness or thickness range, or particular doping limitation.

Graded band gap layer is inserted epitaxially between base region 105 and subcollector region 103.

The top view of FIG. 3B includes dielectric filler material 101, subcollector region 103, base contact metal 106, and external metal contacts 107, 109 and 111.

The side elevation of FIG. 3C includes dielectric filler material 101, semiconductor substrate 102, subcollector region 103, collector region 104, base region 105, base contact metal 106, and graded band gap region 114. Silicon Nitride layer 112 encapsulates HBT 300.

The detailed view of the collector/emitter region of FIG. 3D shows surface current 113 being cut off by graded band gap region 114.

In one aspect of the present invention, the use of graded band gap region 114 is cheaper than vacuum cleaning and is also more effective than vacuum cleaning, polymer encapsulation or Silicon Nitride encapsulation.

While the present invention is described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. A heterojunction bipolar transistor, comprising of:
a graded band gap layer between a subcollector and a base region.

2. The heterojunction bipolar transistor of claim 1, wherein the graded band gap layer is lightly doped.

3. The heterojunction bipolar transistor of claim 1, wherein the graded band gap layer includes InGaAs.

4. The heterojunction bipolar transistor of claim 1, wherein the graded band gap layer includes Indium Aluminum Arsenide.

5. The heterojunction bipolar transistor of claim 1, wherein the graded band gap layer is undepleted under a low voltage bias.

6. The heterojunction bipolar transistor of claim 1, wherein the graded band gap layer is depleted under a high voltage bias.

7. The heterojunction bipolar transistor of claim 1, wherein the graded band gap layer epitaxially grown between the subcollector and base region.

8. A system using a heterojunction bipolar transistor, wherein the heterojunction bipolar transistor, comprising of:
a graded band gap layer between a subcollector and a base region.

9. The system of claim 8, wherein the graded band gap layer is lightly doped.

10. The system of claim 8, wherein the graded band gap layer includes InGaAs.

11. The system of claim 8, wherein the graded band gap layer includes Indium Aluminum Arsenide.

12. The system of claim 8, wherein the graded band gap layer is undepleted under a low voltage bias.

13. The system of claim 8, wherein the graded band gap layer is depleted under a high voltage bias.

14. The system of claim 8, wherein the graded band gap layer epitaxially grown between the subcollector and base region.
